(19) United States
(12) Patent Application Publication
(10) Pub. No.: US 2025/0336356 A1
(43) Pub. Date: Oct. 30, 2025

(54) DISPLAY DEVICE COMPENSATING FOR DEGRADATION AND METHOD OF OPERATING THE SAME

(71) Applicant: ELECTRONICS AND TELECOMMUNICATIONS RESEARCH INSTITUTE, Daejeon (KR)

(72) Inventors: Yongduck KIM, Daejeon (KR); Jin Wook SHIN, Daejeon (KR); In Bok BAEK, Daejeon (KR); Chunwon BYUN, Daejeon (KR); Dasol KIM, Daejeon (KR); Hyungwoo SUH, Daejeon (KR); Seung Wan WOO, Daejeon (KR)

(21) Appl. No.: 19/177,000

(22) Filed: Apr. 11, 2025

(30) Foreign Application Priority Data
Apr. 24, 2024 (KR) 10-2024-0055006

(51) Int. Cl. G09G 3/3233; G09G 3/32

(52) U.S. Cl. CPC G09G 3/3233; G09G 3/32; G09G 2300/0819; G09G 2320/0233; G09G 2320/045; G09G 2360/142

(57) ABSTRACT

Disclosed is a display device, which includes a processor that generates an input analog signal based on an input digital signal, a light-emitting circuit including a first pixel circuit that generates a first pixel signal corresponding to the input analog signal and a light-emitting element that emits a first light based on the first pixel signal, a feedback circuit including a light-receiving element that generates a light-receiving signal by collecting the first light and a feedback signal generator that senses the light-receiving signal to generate a feedback signal, and the processor determines whether a first difference value between the feedback signal and a reference input signal exceeds a threshold value, and generates a first compensation signal based on determining that the first difference value exceeds the threshold value.

### CROSS-REFERENCE TO RELATED APPLICATION

This application claims priority under 35 U.S.C. § 119 to Korean Patent Application No. 10-2024-0055006 filed on Apr. 24, 2024, in the Korean Intellectual Property Office, the disclosures of which are incorporated by reference herein in their entireties.

### BACKGROUND

Embodiments of the present disclosure described herein relate to a display device, and more particularly, relate to a display device for compensating for degradation and a method of operating the same.

Most display devices using light-emitting elements use a current-driven method. In the current-driven method, the voltage applied to a pixel circuit is converted into a current by using transistors, and the magnitude of the current is controlled depending on the applied voltage. In this case, brightness of the light-emitting element is controlled in proportion to the magnitude of the current. Precise current control is necessary for precise and uniform brightness control. Therefore, uniform characteristic compensation for the device characteristics (e.g., threshold voltage, mobility) of the transistor and the device characteristics of the light-emitting element is necessary.

The internal compensation circuit of 4T(transistor)-2C(capacitor) that performs compensation inside the display device has the issue that it is difficult to miniaturize since the internal compensation circuit includes two capacitors. In addition, the internal compensation circuit of 7T-1C requires seven transistors, so it is not suitable for low-area panels.

### SUMMARY

Embodiments of the present disclosure provide a display device for compensating for degradation and a method of operating the same.

According to an embodiment of the present disclosure, a display device includes a processor that generates an input analog signal based on an input digital signal, a light-emitting circuit including a first pixel circuit that generates a first pixel signal corresponding to the input analog signal and a light-emitting element that emits a first light based on the first pixel signal, a feedback circuit including a light-receiving element that generates a light-receiving signal by collecting the first light and a feedback signal generator that senses the light-receiving signal to generate a feedback signal, and the processor determines whether a first difference value between the feedback signal and a reference input signal exceeds a threshold value, and generates a first compensation signal based on determining that the first difference value exceeds the threshold value.

According to an embodiment, the processor may supply the compensation signal to the pixel circuit of the light-emitting circuit.

According to an embodiment, the pixel circuit may generate a second pixel signal corresponding to the compensation signal, the light-emitting element may emit a second light based on the second pixel signal, the light-receiving element may generate a second light-receiving signal by collecting the second light, the feedback signal generator may sense the second light-receiving signal to generate a second feedback signal, and the processor may determine not to generate the compensation signal based on determining that a second difference value between the second feedback signal and the reference input signal does not exceed the threshold value.

According to an embodiment, the reference input signal may be the same as the input digital signal or the input analog signal.

According to an embodiment, the processor may define a reference input time for each time that one row of a panel including the pixel circuit and the light-emitting element is driven.

According to an embodiment, the panel including the pixel circuit and the light-emitting element may be disposed in a stripe type or a pentile type.

According to an embodiment, the feedback circuit may be disposed between a display back plane located on an opposite side of the light-emitting circuit which is located on a front side of the display device and the light-emitting circuit.

According to an embodiment, the display device may further include a reflective element that reflects the first light such that the first light is transferred to the light-receiving element, and the reflective element may be disposed between the light-emitting element and the light-receiving element.

According to an embodiment, the reflective element may include at least one low refractive index layer and at least one high refractive index layer, and the reflective element may totally reflect the first light to the light-receiving element.

According to an embodiment, the high refractive index layer may be a PDL (pixel define layer), and the low refractive index layer may be a black PDL.

According to an embodiment of the present disclosure, a method for compensating for degradation of a display device including a light-emitting circuit, a feedback circuit, and a processor, the method includes generating, by the processor, an input analog signal based on an input digital signal, generating, by a pixel circuit of the light-emitting circuit, a first pixel signal corresponding to the input analog signal, emitting, by a light-emitting element of the light-emitting circuit, a first light based on the first pixel signal, generating, by a light-receiving element of the feedback circuit, a first light-receiving signal by collecting the first light, sensing, by a feedback signal generator of the feedback circuit, the first light-receiving signal to generate a first feedback signal, determining, by the processor, whether a first difference value between the first feedback signal and a reference input signal exceeds a threshold value, and generating, by the processor, a first compensation signal based on determining that the first difference value exceeds the threshold value.

According to an embodiment, the method may further include providing, by the processor, the first compensation signal to the pixel circuit.

According to an embodiment, the method may further include generating, by the pixel circuit, a second pixel signal corresponding to the first compensation signal, emitting, by the light-emitting element, a second light based on the second pixel signal, generating, by the light-receiving element, a second light-receiving signal by collecting the second light, generating, by the feedback signal generator, a second feedback signal by sensing the second light-receiving signal, and determining, by the processor, not to generate a second compensation signal based on determining that a second difference value between the second feedback signal and the reference input signal does not exceed the threshold value.

According to an embodiment, the display device may further include a reflective element, and the reflective element may totally reflect the first light such that the first light reaches the light-receiving element.

According to an embodiment, the feedback circuit may be disposed between a display back plane located on an opposite side of the light-emitting circuit which is located on a front side of the display device and the light-emitting circuit.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a display device, according to an embodiment of the present disclosure.

FIG. 2 is a diagram illustrating a feedback circuit of FIG. 1 according to some embodiments of the present disclosure.

FIG. 3 is a diagram illustrating how a light-receiving element collects light, according to some embodiments of the present disclosure.

FIG. 4 is a diagram illustrating light-emitting elements and light-receiving elements arranged in a stripe type, according to some embodiments of the present disclosure.

FIG. 5 is a diagram illustrating current corresponding to light collected by light-receiving elements of FIG. 4 in a normal state, according to some embodiments of the present disclosure.

FIG. 6 is a diagram illustrating current corresponding to light collected by light-receiving elements of FIG. 4 in an abnormal state, according to some embodiments of the present disclosure.

FIG. 7 is a diagram illustrating light-emitting elements and light-receiving elements arranged in a pentile type, according to some embodiments of the present disclosure.

FIG. 8 is a diagram illustrating current corresponding to light collected by light-receiving elements of FIG. 7 in a normal state, according to some embodiments of the present disclosure.

FIG. 9 is a diagram illustrating current corresponding to light collected by light-receiving elements of FIG. 7 in an abnormal state, according to some embodiments of the present disclosure.

FIG. 10 is a flowchart illustrating how a display device operates, according to some embodiments of the present disclosure.

### DETAILED DESCRIPTION

Hereinafter, embodiments of the present disclosure will be described in detail and clearly to such an extent that an ordinary one in the art easily implements the present disclosure.

The terms “unit”, “module”, etc. to be used below and function blocks illustrated in drawings may be implemented in the form of a software component, a hardware component, or a combination thereof. Below, to describe the technical idea of the present disclosure clearly, a description associated with identical components will be omitted.

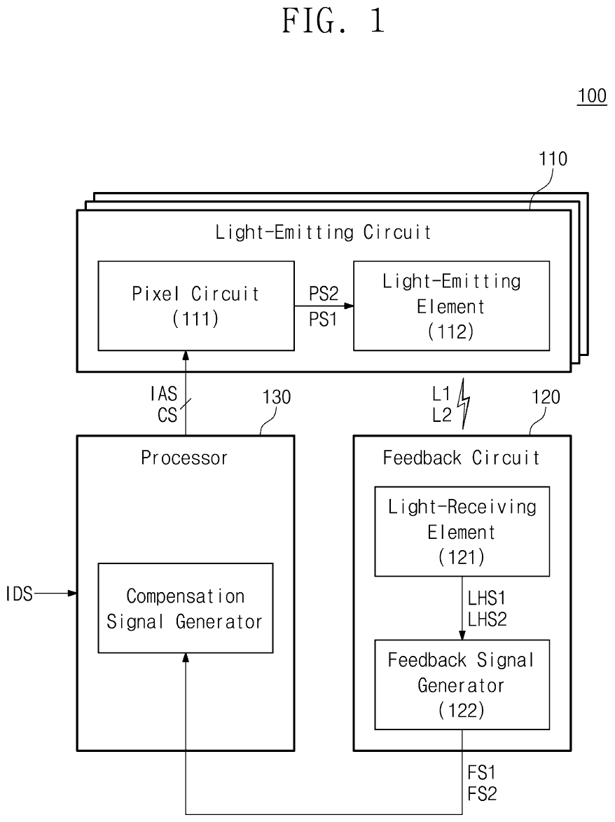

FIG. 1 is a block diagram illustrating a display device 100, according to an embodiment of the present disclosure. Referring to FIG. 1, the display device 100 may include a light-emitting circuit 110, a feedback circuit 120, and a processor 130.

The light-emitting circuit 110 may emit light corresponding to data to be displayed by the display device 100. The light-emitting circuit 110 may include a pixel circuit 111 and a light-emitting element 112. In FIG. 1, it is illustrated as including one pixel circuit 111 and one light-emitting element 112, but the scope of the present disclosure is not limited thereto. Alternatively, the display device 100 may include a plurality of light-emitting circuits. In other words, the display device 100 may include a plurality of sets of pixel circuits and light-emitting elements. The display device 100 may include at least one panel in which the plurality of sets of pixel circuits and light-emitting elements are arranged in an array form. The array may include a plurality of rows and a plurality of columns.

The pixel circuit 111 may receive an input analog signal IAS from the processor 130. The pixel circuit 111 may generate a first pixel signal PS1 corresponding to the input analog signal IAS. The input analog signal IAS may be a voltage signal or a current signal corresponding to data to be displayed by the display device 100. The pixel circuit 111 may transfer the first pixel signal PS1 to the light-emitting element 112.

The light-emitting element 112 may emit a first light L1 based on the first pixel signal PS1. The first light L1 emitted from the light-emitting element 112 may correspond to one of green, red, and blue. For example, the first light L1 may be included in one of the regions corresponding to green, red, and blue among the visible light regions, respectively. A light-emitting element capable of emitting the first light L1 corresponding to green may be referred to as a “G” light-emitting element. A light-emitting element capable of emitting the first light L1 corresponding to red may be referred to as an “R” light-emitting element. A light-emitting element capable of emitting the first light L1 corresponding to blue may be referred to as a “B” light-emitting element.

In some embodiments, the light-emitting element 112 may be an OLED (Organic Light Emitting Diode) element.

The feedback circuit 120 may collect the first light L1 emitted from the light-emitting circuit 110 and may generate a first feedback signal FS1 for determining whether there is an error (e.g., an error due to degradation) in the light-emitting circuit 110. The feedback circuit 120 may include a light-receiving element 121 and a feedback signal generator 122.

The light-receiving element 121 may collect the first light L1 emitted from the light-emitting element 112. For example, the light-receiving element 121 may be a photodiode. The light-receiving element 121 may sense the first light L1 and may generate an electrical signal corresponding to the first light L1 as a first light-receiving signal LHS1.

The feedback signal generator 122 may sense the first light-receiving signal LHS1 output from the light-receiving element 121 to generate the first feedback signal FS1. The first feedback signal FS1 may represent an electrical signal formed by the accumulation of the first light-receiving signal LHS1. The feedback signal generator 122 may provide the first feedback signal FS1 to the processor 130.

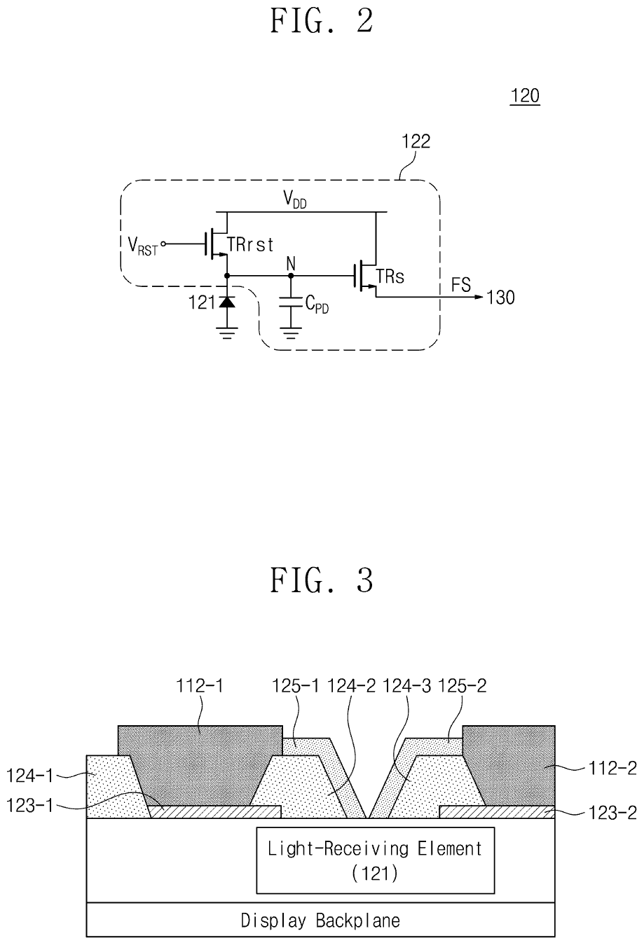

A more detailed description of the feedback circuit 120 will be described later with reference to FIG. 2.

The processor 130 may receive an input digital signal IDS and may generate the input analog signal IAS based on the input digital signal IDS. The input digital signal IDS may represent image data to be displayed by the display device 100. The input digital signal IDS may include at least one digital bit. The input analog signal IAS may refer to a current signal or a voltage signal that controls the pixel circuit 111 such that the light-emitting circuit 110 emits light corresponding to the input digital signal IDS. The processor 130 may provide the input analog signal IAS to the pixel circuit 111.

The processor 130 may include a compensation signal generator. The compensation signal generator may generate a compensation signal CS based on the first feedback signal FS1. The compensation signal generator may determine whether the light-emitting circuit 110 is degradated based on a comparison operation of the first feedback signal FS1 and a reference input signal. In addition, the compensation signal generator may generate the compensation signal CS based on determining that the light-emitting circuit 110 is degradated. The compensation signal CS may represent the sum of the existing input analog signal IAS and an additional current or voltage signal for compensating for an error due to degradation of the light-emitting circuit 110. The reference input signal may be an analog signal or a digital signal corresponding to the analog signal that the first feedback signal FS1 is expected to have when the light-emitting circuit 110 is not degradated (i.e., when no error occurs). The reference input signal may be determined in advance based on the input digital signal IDS and the input analog signal IAS.

In some embodiments, the reference input signal may be the same as the input digital signal IDS or the input analog signal IAS.

In some embodiments, the compensation signal generator may convert the first feedback signal FS1 into a digital signal. The compensation signal generator may compare the input digital signal IDS as the reference input signal with a feedback signal converted into a digital signal.

In some embodiments, when the first feedback signal FS1 and the reference input signal are analog signals, the compensation signal generator may determine whether a first difference value (e.g., a difference value of a voltage level or a difference value of a current intensity) between the first feedback signal FS1 and the reference input signal exceeds a threshold value. The threshold value may be a value determined in advance. The compensation signal generator may generate the compensation signal CS based on determining that the first difference value exceeds the threshold value. In this case, the compensation signal may determine the magnitude (voltage level or current intensity) of the compensation signal CS depending on the first difference value.

For example, when the first feedback signal FS1 is less than the reference input signal, the compensation signal CS may be greater than the first input analog signal (i.e., the voltage level is higher or the current intensity is larger). As another example, when the first feedback signal FS1 is greater than the reference input signal, the compensation signal CS may be less than the first input analog signal (i.e., the voltage level is smaller or the current intensity is smaller).

In some embodiments, when the first feedback signal FS1 and the reference input signal are digital signals, the compensation signal generator may determine whether the first feedback signal FS1 is the same as the reference input signal. The compensation signal generator may generate the compensation signal CS based on determining that the first feedback signal FS1 is not the same as the reference input signal. As another example, the compensation signal generator may determine whether the number of mismatches between the digital bits of the first feedback signal FS1 and the digital bits of the reference input signal exceeds a threshold value. The compensation signal generator may generate the compensation signal CS based on determining that the number of mismatches exceeds the threshold value.

The processor 130 may provide the compensation signal CS to the pixel circuit 111.

The pixel circuit 111 may generate a second pixel signal PS2 corresponding to the compensation signal CS. The pixel circuit 111 may provide the second pixel signal PS2 to the light-emitting element 112. The light-emitting element 112 may emit a second light L2 based on the second pixel signal PS2. The light-receiving element 121 may collect the second light L2 and may generate a second light-receiving signal LHS2. The feedback signal generator 122 may sense the second light-receiving signal LHS2 and may generate a second feedback signal FS2. The compensation signal generator may determine not to generate the compensation signal based on the comparison operation of the second feedback signal and the reference input signal.

However, when the second feedback signal is still different from the reference input signal, the compensation signal generator may generate the second compensation signal (e.g., the compensation signal CS described above is the first compensation signal) based on a second difference value between the second feedback signal and the reference input signal, and may repeat operations described above.

The display device 100 according to the present disclosure may sense light emitted by the light-emitting circuit 110 through the feedback circuit 120 located within the display device 100 and may provide the feedback signal FS to the processor 130, and the processor 130 may compensate for degradation of the light-emitting circuit 110 depending on the feedback signal of the feedback circuit 120, thereby compensating in real time not only for the degradation of general driving transistors, but also for the degradation of the light-emitting element 112 and the degradation over time. Therefore, the lifetime of the display device 100 is increased, and since the compensation is performed within the display device 100, vibration and noise from the outside do not intervene, so the precision of the compensation may be improved.

FIG. 2 is a diagram illustrating the feedback circuit 120 of FIG. 1 according to some embodiments of the present disclosure. Referring to FIG. 2, the feedback circuit 120 may include the light-receiving element 121 and the feedback signal generator 122.

The light-receiving element 121 is illustrated as a photodiode, but the scope of the present disclosure is not limited thereto. One end of the light-receiving element 121 may be connected to a ground voltage, and the other end may be connected to a sensing node “N”. The light-receiving element 121 may sense the first light L1 emitted from the light-emitting element 112 of FIG. 1 so as to convert into an electrical signal.

The feedback signal generator 122 may include a reset transistor TRrst, a sensing transistor TRs, and a capacitor “C”. A gate terminal of the reset transistor TRrst may be connected to a reset voltage Vrst, a drain terminal of the reset transistor TRrst may be connected to a power supply voltage VDD, and a source terminal of the reset transistor TRrst may be connected to the sensing node “N”. The capacitor “C” may be connected between the ground voltage and the sensing node “N”. The capacitor “C” may accumulate electrical signals from the light-receiving element 121.

A gate terminal of the sensing transistor TRs may be connected to the sensing node “N”, a drain terminal of the sensing transistor TRs may be connected to the power supply voltage VDD, and a source terminal of the sensing transistor TRs may output the feedback signal FS which is an analog signal so as to be provide to the processor 130. The sensing transistor TRs may output the feedback signal FS based on charges stored in the capacitor “C”.

The reset transistor TRrst and the sensing transistor TRs are each illustrated as an NMOS transistor, but the scope of the present disclosure is not limited thereto and may be implemented by a combination of other types of transistors or electronic elements.

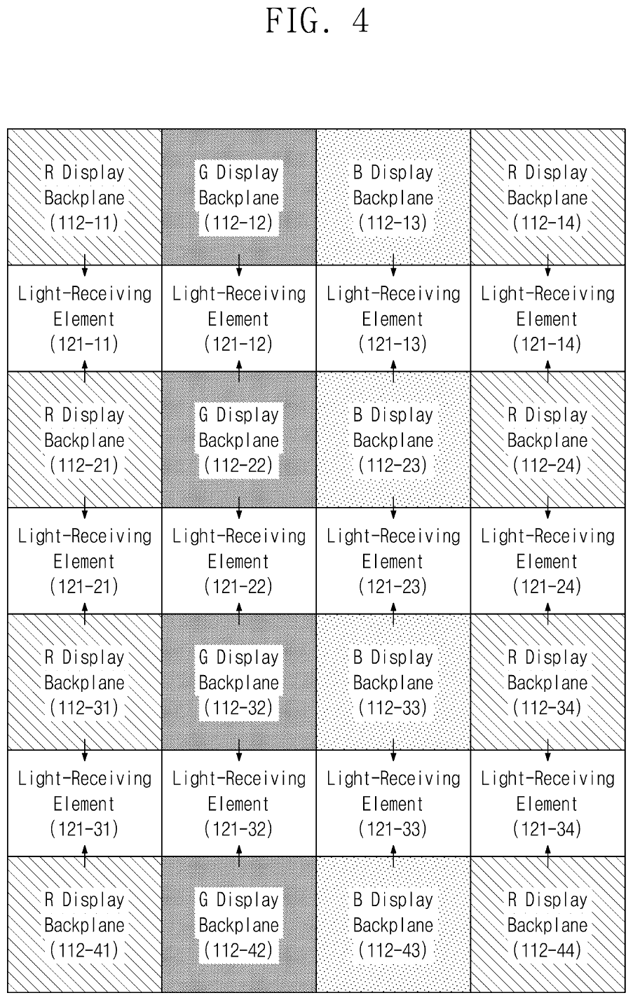

FIG. 3 is a diagram illustrating how a light-receiving element collects light, according to some embodiments of the present disclosure. Referring to FIG. 3, it is described that the light-receiving element 121 of FIG. 1, which collects light emitted from two light-emitting elements, collects light output from the light-emitting circuit.

The light-receiving element 121 may collect light emitted from two light-emitting elements instead of one light-emitting element. For example, the light-receiving element 121 may sense light emitted from each of a first light-emitting element 112-1 and a second light-emitting element 112-2. Each of the first light-emitting element 112-1 and the second light-emitting element 112-2 may correspond to the light-emitting element 112 of FIG. 1.

The first light-emitting element 112-1 and the second light-emitting element 112-2 may be arranged side by side with each other. For example, the first light-emitting element 112-1 and the second light-emitting element 112-2 may be arranged sequentially in the same column.

The display device 100 may include a first reflective element that reflects light emitted from the first light-emitting element 112-1 to reach the light-receiving element 121. The first reflective element may be arranged between the first light-emitting element 112-1 and the light-receiving element 121.

For example, the first reflective element may include a first reflective electrode 123-1, at least one high refractive index layer 124-2, and at least one low refractive index layer 125-1. The high refractive index layer 124-2 may be a first PDL (Pixel Define Layer) PDL1. In addition, the low refractive index layer 125-1 may be a first black PDL “bPDL1”.

The first reflective element may use the high refractive index layer 124-2 and the low refractive index layer 125-1 to totally reflect light emitted from the first light-emitting element to the light-receiving element 121.

The display device 100 may include a second reflective element that reflects light emitted from the second light-emitting element 112-2 to reach the light-receiving element 121. The second reflective element may be arranged between the second light-emitting element 112-2 and the light-receiving element 121.

For example, the second reflective element may include a second reflective electrode 123-2, at least one high refractive index layer 124-3, and at least one low refractive index layer 125-2. The high refractive index layer 124-3 may be a second PDL “PDL2”. In addition, the low refractive index layer 125-2 may be a second black PDL “bPDL2”.

The second reflective element may totally reflect light emitted from the second light-emitting element 112-2 using the high refractive index layer 124-3 and the low refractive index layer 125-2.

In some embodiments, the light-receiving element 121 may be located between the light-emitting circuit and the display backplane within the display device 100. The display backplane may be the rearmost surface located opposite the light-emitting circuit located on the front surface of the display device 100. In detail, the front surface including the light-emitting circuit may refer to the surface closest to a user looking at the display device, and the display backplane may refer to the surface furthest from the user.

A high refractive index layer 124-1 may be used to reflect light emitted from the first light-emitting element 112-1 to the light-receiving element located between other light-emitting element arranged parallel to the first light-emitting element 112-1 not illustrated in FIG. 3 and the first light-emitting element 112-1.

For convenience of description, FIG. 3 briefly illustrates only the light-receiving element 121 located between the light-emitting elements 112-1 and 112-2 and the display backplane, but the present disclosure is not limited thereto. Various configurations may be further arranged between the light-receiving element and the display backplane, and various configurations may be further arranged between the light-receiving element and the light-emitting elements 112-1 and 112-2.

FIG. 4 is a diagram illustrating light-emitting elements 112-11 to 112-44 and light-receiving elements 121-11 to 121-34 arranged in a stripe type, according to some embodiments of the present disclosure. Referring to FIG. 4, the light-emitting elements 112-11 to 112-44 and the light-receiving elements 121-11 to 121-34 arranged in a stripe type are illustrated.

In the light-emitting elements 112-11 to 112-44 arranged in the stripe type, the light-emitting elements corresponding to the same color may be arranged in the same row. For example, “R” light-emitting elements 112-11 to 112-41 may be arranged in a first row. “G” light-emitting elements 112-12 to 112-42 may be arranged in a second row. “B” light-emitting elements 112-13 to 112-43 may be arranged in a third row. “R” light-emitting elements 112-14 to 112-44 may be arranged in a fourth row.

Light emitted from two light-emitting elements arranged side by side above and below may be collected by one light-receiving element. For example, the “R” light-emitting element 112-11, the “R” light-emitting element 112-21, and the light-receiving element 121-11 may correspond to the first light-emitting element 112-1, the second light-emitting element 112-2, and the light-receiving element 121 of FIG. 3, respectively. In FIG. 4, the light emitted from the light-emitting element is transferred to the light-receiving element as illustrated by arrows.

In some embodiments, the panel of the display device may be sequentially programmed from the first row downward or from the first row upward. For example, when sequentially programming from the first row to the fourth row, the light-emitting elements located in the row being programmed may be in a black state (i.e., not emitting light).

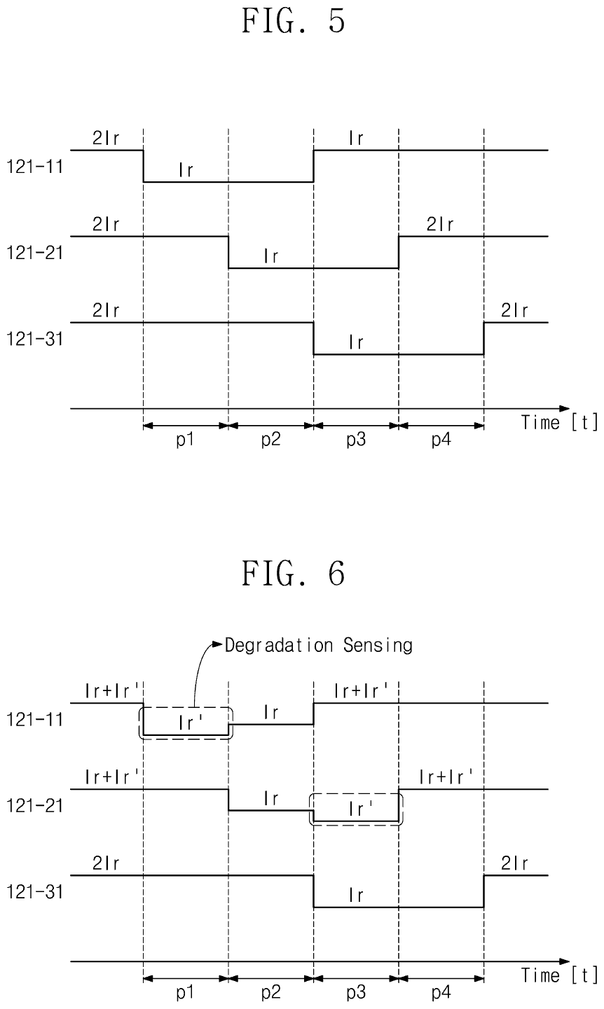

The row that becomes the black state may be changed at regular intervals (e.g., the time that one row is driven). A more detailed description of this will be described later with reference to FIG. 5.

FIG. 5 is a diagram illustrating a current corresponding to light collected by the light-receiving elements 121-11 and 121-31 of FIG. 4 in a normal state, according to some embodiments of the present disclosure. The light-receiving element 121-11 may collect light emitted from the “R” light-emitting element 112-11 and the “R” light-emitting element 112-21 of FIG. 4 so as to be output as a current. The light-receiving element 121-21 may collect light emitted from the “R” light-emitting element 112-21 and the “R” light-emitting element 112-31 of FIG. 4 so as to be output as a current. The light-receiving element 121-31 may collect light emitted from the “R” light-emitting element 112-31 and the “R” light-emitting element 112-41 of FIG. 4 so as to be output as a current.

The current collected by the light-receiving element 121-11 from the light-emitting element 112-11 may be an R-th current “Ir”. In the normal state, since there is little deviation between the light-emitting elements of the same type, the light-receiving element 121-11 may collect the R-th current “Ir” from each of the “R” light-emitting elements 112-11 and 112-21. The light-emitting element 121-21 and the light-emitting element 121-31 may each collect the R-th currents “Ir” from adjacent “R” light-emitting elements, similar to the light-emitting element 121-11.

A first section p1 may be a section in which the first row of FIG. 3 is programmed (i.e., the first row is driven). Before the first section p1, other rows than the first to fourth rows of FIG. 3 are programmed, and the light-receiving elements 121-11, 121-21, and 121-31 may generate twice the R-th current “Ir”.

During the first section p1, the “R” light-emitting element 112-11 is in a black state, so the “R” light-emitting element 112-11 may not emit light to the light-receiving element 121-11. Therefore, the light-receiving element 121-11 may generate only the R-th current “Ir”. The light-receiving elements 121-21 and 121-31 may generate twice the R-th current “Ir”.

A second section p2 may be a section in which the second row of FIG. 3 is programmed. During the second section p2, the “R” light-emitting element 112-21 is in a black state, and therefore may not emit light to the light-receiving elements 121-11 and 121-21. Therefore, the light-receiving elements 121-11, 121-21 may only generate the R-th current “Ir”. The light-receiving element 121-31 may generate twice the R-th current “Ir”.

A third section p3 may be a section in which the third row of FIG. 3 is programmed. During the third section p3, the “R” light-emitting element 112-31 is in a black state, and therefore may not emit light to the light-receiving elements 121-21 and 121-31. Therefore, the light-receiving elements 121-21, 121-31 may only generate the R-th current “Ir”. The light-receiving element 121-11 may generate twice the R-th current “Ir”.

A fourth section p4 may be a section in which the fourth row of FIG. 4 is programmed. During the fourth section p4, the “R” light-emitting element 112-41 is in a black state, and therefore may not emit light to the light-receiving element 121-31 (although not illustrated in FIG. 3, the “R” light-emitting element 112-41 also does not emit light to the light-receiving element located between the light-emitting elements of the fourth and fifth rows). Therefore, the light-receiving element 121-31 may generate only the R-th current “Ir”. The light-receiving elements 121-11 and 121-21 may generate twice the R-th current “Ir”.

After the fourth section p4, the light-receiving element 121-31 may again generate twice the R-th current “Ir”.

In some embodiments, the current signal corresponding to the light collected by the light-receiving elements 121-11, 121-21, and 121-31 in a normal state may correspond to the reference input signal described above in FIG. 1.

In some embodiments, as in FIG. 5, the reference input signal may be defined for each time that one row of the panel including the pixel circuit and the light-emitting elements is driven.

FIG. 6 is a diagram illustrating currents corresponding to the light collected by the light-receiving elements 121-11, 121-21, and 121-31 of FIG. 4 in an abnormal state, according to some embodiments of the present disclosure. Referring to FIG. 6, currents corresponding to the light collected by the light-receiving elements 121-11, 121-21, and 121-31 in an abnormal state (e.g., when degradation of some light-emitting elements occurs) are each described. The light-receiving elements 121-11, 121-21, and 121-31, the first to fourth sections p1 to p4, and the R-th current “Ir” of FIG. 6 correspond to the components corresponding to the same reference numbers of FIG. 5, respectively. However, a case in which a characteristic deviation (e.g., degradation) different from other “R” light-emitting elements occurs in the “R” light-emitting element 112-21 will be described below with reference to FIG. 6 as an example.

The abnormal light emitted by the “R” light-emitting element 112-21 may be different from the normal light emitted by other “R” light-emitting elements 112-11 and 112-31. The light-receiving elements 121-11 and 121-21 may generate an R-th abnormal current Ir′ from the light emitted by the “R” light-emitting element 112-21.

Before the first section p1, the light-receiving elements 121-11 and 121-21 may generate a current equal to the sum of the R-th current “Ir” and the R-th abnormal current Ir'. The light-receiving element 121-31 may generate twice the R-th current “Ir”.

During the first section p1, the “R” light-emitting element 112-11 is in a black state, so the “R” light-emitting element 112-11 may not emit light to the light-receiving element 121-11. The light-receiving element 121-11 may generate the R-th abnormal current Ir'. The light-receiving element 121-21 may generate a current equal to the sum of the R-th current “Ir” and the R-th abnormal current Ir'. The light-receiving element 121-31 may generate twice the R-th current “Ir”.

During the second section p2, the “R” light-emitting element 112-21 is in a black state, and therefore may not emit light to the light-receiving elements 121-11 and 121-21. The light-receiving element 121-11 may generate the R-th current “Ir”. The light-receiving element 121-21 may generate the R-th current “Ir”. The light-receiving element 121-31 may generate twice the R-th current “Ir”.

During the third section p3, the “R” light-emitting element 112-31 is in a black state, and therefore may not emit light to the light-receiving elements 121-21 and 121-31. The light-receiving element 121-11 may generate a current equal to the sum of the R-th current “Ir” and the R-th abnormal current Ir'. The light-receiving element 121-21 may generate the R-th abnormal current Ir'. The light-receiving element 121-31 may generate the R-th current “Ir”.

During the fourth section p4, the “R” light-emitting element 112-41 is in a black state, so the “R” light-emitting element 112-41 may not emit light to the light-receiving element 121-31. The light-receiving element 121-11 may generate a current equal to the sum of the R-th current “Ir” and the R-th abnormal current Ir′. The light-receiving element 121-21 may generate a current equal to the sum of the R-th current “Ir” and the R-th abnormal current Ir′. The light-receiving element 121-31 may generate the R-th current “Ir”.

Immediately after the fourth section p4, although not illustrated in FIG. 6, the “R” light-emitting element located in the fifth row may be in a black state. Therefore, the light-receiving elements 121-11 and 121-21 may generate a current equal to the sum of the R-th current “Ir” and the R-th abnormal current Ir'. The light-receiving element 121-31 may generate twice the R-th current “Ir”.

In this case, when comparing FIG. 5 with FIG. 6, the magnitudes of the currents of the light-receiving elements 121-11 and 121-21 immediately before the first section p1 may be different, the magnitudes of the currents of the light-receiving element 121-11 during the first section p1 may be different, and the magnitudes of the currents of the light-receiving element 121-21 during the third section p3 may be different. The processor 130 of FIG. 1 may generate a compensation signal based on the above-described difference.

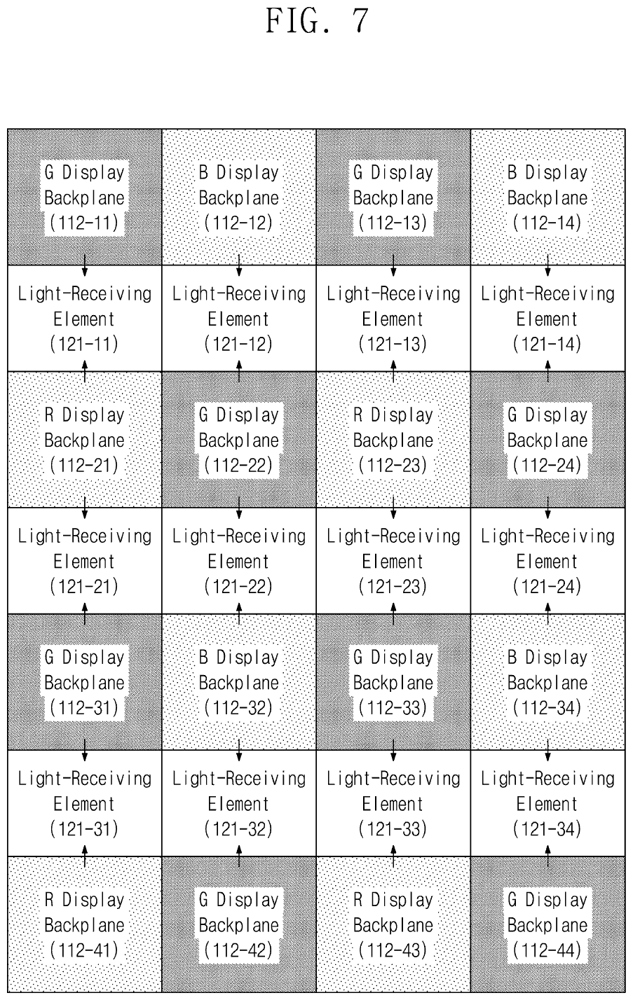

FIG. 7 is a drawing illustrating light-emitting elements 112-11 to 112-44 and light-receiving elements 121-11 to 121-34 arranged in a pentile type, according to some embodiments of the present disclosure. Referring to FIG. 7, the light-emitting elements 112-11 to 112-44 and the light-receiving elements 121-11 to 121-34 arranged in the pentile type are illustrated.

The light-emitting elements 112-11 to 112-44 arranged in the pentile type may be arranged in an array of 2 rows and 2 columns including a “G” light-emitting element arranged in a first row and a first column, a “B” light-emitting element arranged in the first row and a second column, the “R” light-emitting element arranged in a second row and the first column, and the “G” light-emitting element arranged in the second row and the second column, and may be repeated up, down, left, and right as illustrated in FIG. 7. For convenience of description, only an array of 4 rows and 4 columns is illustrated, but the scope of the present disclosure is not limited thereto.

Light emitted from two light-emitting elements arranged side by side above and below may be collected by one light-receiving element. For example, the “G” light-emitting element 112-11, the “R” light-emitting element 112-21, and the light-receiving element 121-11 may correspond to the first light-emitting element 112-1, the second light-emitting element 112-2, and the light-receiving element 121 of FIG. 4, respectively. In FIG. 7, the light emitted from the light-emitting element is transferred to the light-receiving element as illustrated by arrows.

In some embodiments, the panel of the display device may be sequentially programmed from the first row downward or from the first row upward. For example, when sequentially programming from the first row to the fourth row, the light-emitting elements located in the row being programmed may be in a black state (i.e., not emitting light).

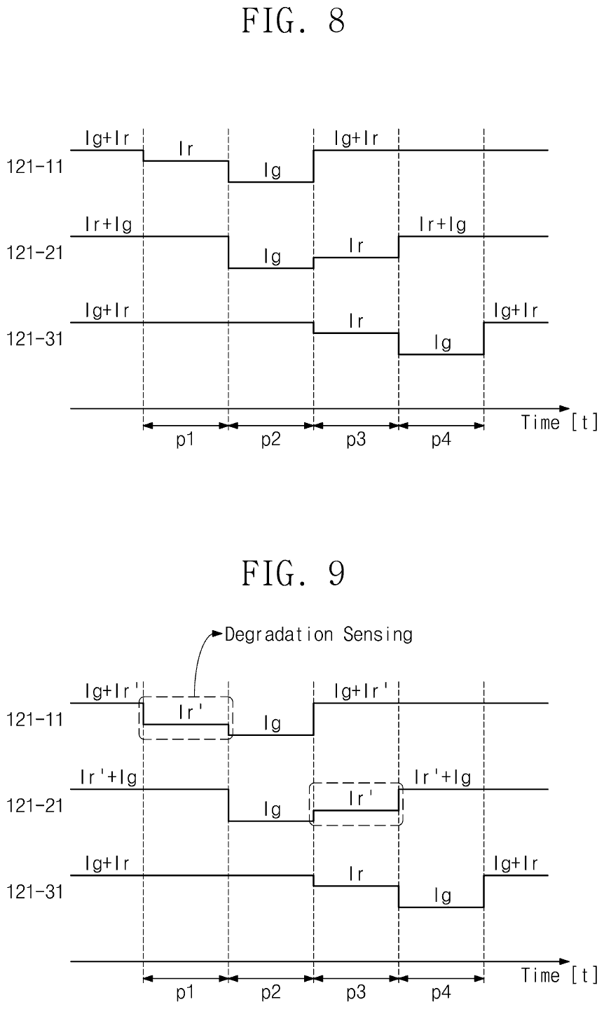

The row that becomes the black state may be changed at regular intervals (e.g., the time that one row is driven). A more detailed description of this will be described later with reference to FIG. 8.

FIG. 8 is a diagram illustrating currents corresponding to the light collected by the light-receiving elements 121-11, 121-21, and 121-31 of FIG. 7 in a normal state, according to some embodiments of the present disclosure. Referring to FIG. 8, currents corresponding to light collected by the light-receiving elements 121-11, 121-21, and 121-31 in a normal state are respectively described. The light-receiving elements 121-11, 121-21, and 121-31 and the first to fourth sections p1 to p4 of FIG. 8 correspond to the components corresponding to the same reference numbers of FIG. 5, respectively.

A G-th current “Ig” may represent the current generated by the light-receiving element by collecting light emitted from the “G” light-emitting element.

Before the first section p1, the light-receiving elements 121-11, 121-21, and 121-31 may generate a current equal to the sum of the G-th current “Ig” and the R-th current “Ir”.

During the first section p1, the “G” light-emitting element 112-11 is in a black state, so the “G” light-emitting element 112-11 may not emit light to the light-receiving element 121-11. The light-receiving element 121-11 may generate the R-th current “Ir”. The light-receiving elements 121-21 and 121-31 may generate a current equal to the sum of the R-th current “Ir” and the G-th current “Ig”.

During the second section p2, the “R” light-emitting element 112-21 is in a black state, and therefore may not emit light to the light-receiving elements 121-11 and 121-21. The light-receiving elements 121-11 and 121-21 may generate the G-th current “Ig”. The light-receiving element 121-31 may generate a current equal to the sum of the R-th current “Ir” and the G-th current “Ig”.

During the third section p3, the “G” light-emitting element 112-31 is in a black state, and therefore may not emit light to the light-receiving elements 121-21 and 121-31. The light-receiving element 121-11 may generate a current equal to the sum of the R-th current “Ir” and the G-th current “Ig”. The light-receiving elements 121-21 and 121-31) may generate the R-th current “Ir”.

During the fourth section p4, the “R” light-emitting element 112-41 is in a black state, so the “R” light-emitting element 112-41 may not emit light to the light-receiving element 121-31. The light-receiving elements 121-11 and 121-21 may generate a current equal to the sum of the R-th current “Ir” and the G-th current “Ig”. The light-receiving element 121-31 may generate the G-th current “Ig”.

Immediately after the fourth section p4, the light-emitting elements 112-11, 112-21, and 112-31 may not be in a black state. Therefore, the light-receiving elements 121-11, 121-21, and 121-31 may generate a current equal to the sum of the R-th current “Ir” and the G-th current “Ig”.

In some embodiments, the current signal corresponding to the light collected by the light-receiving elements 121-11, 121-21, and 121-31 in a normal state may correspond to the reference input signal described above in FIG. 1.

FIG. 9 is a diagram illustrating currents corresponding to the light collected by the light-receiving elements 121-11, 121-21, and 121-31 of FIG. 7 in an abnormal state, according to some embodiments of the present disclosure. Referring to FIG. 9, currents corresponding to the light collected by the light-receiving elements 121-11, 121-21, and 121-31 in an abnormal state (e.g., when degradation of some light-emitting elements occurs) are each illustrated. The light-receiving elements 121-11, 121-21, and 121-31, the first to fourth sections p1 to p4, the R-th current “Ir”, and the G-th current “Ig” of FIG. 9 correspond to the components corresponding to the same reference numbers of FIG. 8, respectively. However, a case in which a characteristic deviation (e.g., degradation) different from normal “R” light-emitting elements occurs in the “R” light-emitting element 112-21 will be described below with reference to FIG. 9 as an example.

The abnormal light emitted by the “R” light-emitting element 112-21 may be different from the normal light emitted by other “R” light-emitting elements. The light-receiving elements 121-11 and 121-21 may generate an R-th abnormal current Ir′ from the light emitted by the “R” light-emitting element 112-21.

Before the first section p1, the light-receiving elements 121-11 and 121-21 may generate a current equal to the sum of the G-th current “Ig” and the R-th abnormal current Ir′. The light-receiving element 121-31 may generate a current equal to the sum of the G-th current “Ig” and the R-th current “Ir”.

In the first section p1, since the “G” light-emitting element 112-11 is in a black state, the “G” light-emitting element 112-11 may not emit light to the light-receiving element 121-11. Therefore, the light-receiving element 121-11 may generate the R-th abnormal current Ir′. The light-receiving element 121-21 may generate a current equal to the sum of the G-th current “Ig” and the R-th abnormal current Ir′. The light-receiving element 121-31 may generate a current equal to the sum of the G- th current “Ig” and the R-th current “Ir”.

In the second section p2, since the “R” light-emitting element 112-21 is in a black state, the “R” light-emitting element 112-21 may not emit light to the light-receiving elements 121-11 and 121-21. Therefore, the light-receiving elements 121-11 and 121-21 may generate the G-th current “Ig”. The light-receiving element 121-31 may generate a current equal to the sum of the G-th current “Ig” and the R-th current “Ir”.

In the third section p3, since the “G” light-emitting element 112-31 is in a black state, the “G” light-emitting element 112-31 may not emit light to the light-receiving elements 121-21 and 121-31. The light-receiving element 121-11 may generate a current equal to the sum of the G-th current “Ig” and the R-th abnormal current Ir′. The light-receiving element 121-21 may generate the R-th abnormal current Ir′. The light-receiving element 121-31 may generate the R-th current “Ir”.

In the fourth section p4, since the “R” light-emitting element 112-41 is in a black state, the “R” light-emitting element 112-41 may not emit light to the light-receiving element 121-31. Therefore, the light-receiving elements 121-11 and 121-21 may generate a current equal to the sum of the G-th current “Ig” and the R-th abnormal current Ir′. The light-receiving element 121-31 may generate the G-th current “Ig”.

Immediately after the fourth section p4, the light-emitting elements 112-11 to 112-44 located in the first to fourth rows may not be in a black state. Therefore, the light-receiving elements 121-11 and 121-21 may generate a current equal to the sum of the G-th current “Ig” and the R-th abnormal current Ir′. The light-receiving element 121-31 may generate a current equal to the sum of the G-th current “Ig” and the R-th current “Ir”.

In this case, when comparing FIG. 8 with FIG. 9, the magnitudes of the currents of the light-receiving elements 121-11 and 121-21 immediately before the first section p1 may be different, the magnitudes of the currents of the light-receiving element 121-11 during the first section p1 may be different, and the magnitudes of the currents of the light-receiving element 121-21 during the third section p3 may be different. The processor 130 of FIG. 1 may generate a compensation signal based on the above-described difference.

In some embodiments, as in FIG. 9, the reference input signal may be defined for each time that one row of the panel including the pixel circuit and the light-emitting elements is driven.

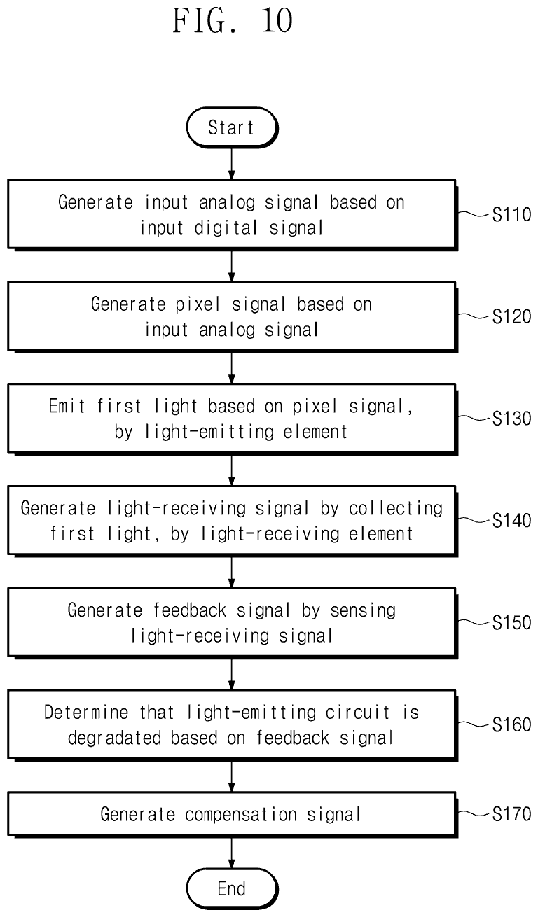

FIG. 10 is a flowchart illustrating how a display device in FIG. 1 operates, according to some embodiments of the present disclosure. Referring to FIG. 10, a method of operating the display device will be described. A light-emitting element and a light-receiving element of FIG. 10 correspond to the light-emitting element 112 and the light-receiving element 121 of FIG. 1, respectively.

In operation S110, the display device may generate an input analog signal based on an input digital signal by the processor.

In operation S120, the display device may generate a first pixel signal corresponding to the input analog signal by the pixel circuit of the light-emitting circuit.

In operation S130, the display device may emit a first light based on the first pixel signal by the light-emitting element of the light-emitting circuit.

In operation S140, the display device may generate a first light-receiving signal by collecting the first light by the light-receiving element of the feedback circuit.

In operation S150, the display device may generate a first feedback signal by sensing the first light-receiving signal by the feedback signal generator of the feedback circuit.

In operation S160, the display device may determine whether the light-emitting circuit is degradated based on a first comparison operation of the first feedback signal with the reference input signal by the processor.

In some embodiments, operation S160 may include determining whether a first difference value between a reference input signal and a feedback signal is greater than or equal to a threshold value, and determining that the light-emitting circuit is degradated based on determining that the first difference value is greater than or equal to the threshold value.

In operation S170, the display device may generate a first compensation signal based on determining that the light-emitting circuit is degradated, by the processor.

Although not illustrated in the flowchart of FIG. 10, the display device may provide the first compensation signal to the pixel circuit, by the processor. In addition, the display device may generate a second pixel signal corresponding to the first compensation signal by the pixel circuit, may emit a second light based on the second pixel signal by the light-emitting element, may collect the second light by the light-receiving element to generate a second light-receiving signal, may sense the second light-receiving signal by the feedback signal generator to generate a second feedback signal, and may determine not to generate the second compensation signal based on a second comparison operation of the second feedback signal with the reference input signal by the processor.

In some embodiments, the processor may determine not to generate the second compensation signal based on determining that the second difference value between the second feedback signal and the reference input signal does not exceed the threshold value.

In some embodiments, the feedback circuit may be disposed between the display back plane located on an opposite side of the light-emitting circuit which is located on a front side of the display device and the light-emitting circuit. In detail, the feedback circuit may be disposed within the display device, and the display device may not have a separate external device for feedback.

According to an embodiment of the present disclosure, a display device for compensating for degradation and a method of operating the same are provided.

In addition, the display device and the method of operating the same are provided in which the degradation of the image quality of the display device due to changes in the characteristics of the transistor and the light-emitting element and degradation over time is suppressed, by sensing the light emitted from the light-emitting element in real time and controlling the current applied to the transistor that drives the light-emitting element depending on the sensed light.

As used herein, including in the claims, “or” as used in a list of items (e.g., a list of items prefaced by a phased such as “at least one of” or “one or more of” or “one or both of” indicates as inclusive list such that, for example, a list of at least one of A, B, or C means A or B or C or AB or AC or BC or ABC (i.e., A and B and C).

The above descriptions are detail embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure. Therefore, the scope of the present disclosure should not be limited to the above-described embodiments and should be defined by not only the claims to be described later, but also those equivalent to the claims of the present disclosure.

What is claimed is:

1. A display device comprising:
a processor configured to generate an input analog signal based on an input digital signal;
a light-emitting circuit including a first pixel circuit configured to generate a first pixel signal corresponding to the input analog signal and a light-emitting element configured to emit a first light based on the first pixel signal; and
a feedback circuit including a light-receiving element configured to generate a light-receiving signal by collecting the first light and a feedback signal generator configured to sense the light-receiving signal to generate a feedback signal, and
wherein the processor is further configured to:
determine whether a first difference value between the feedback signal and a reference input signal exceeds a threshold value; and
generate a first compensation signal based on determining that the first difference value exceeds the threshold value.

2. The display device of claim 1, wherein the processor is further configured to supply the compensation signal to the pixel circuit of the light-emitting circuit.

3. The display device of claim 2, wherein the pixel circuit is further configured to generate a second pixel signal corresponding to the compensation signal,
wherein the light-emitting element emits a second light based on the second pixel signal,
wherein the light-receiving element generates a second light-receiving signal by collecting the second light,
wherein the feedback signal generator senses the second light-receiving signal to generate a second feedback signal, and
wherein the processor determines not to generate the compensation signal based on determining that a second difference value between the second feedback signal and the reference input signal does not exceed the threshold value.

4. The display device of claim 1, wherein the reference input signal is the same as the input digital signal or the input analog signal.

5. The display device of claim 4, wherein the processor is configured to:
define a reference input time for each time that one row of a panel including the pixel circuit and the light-emitting element is driven.

6. The display device of claim 1, wherein the panel including the pixel circuit and the light-emitting element is disposed in a stripe type or a pentile type.

7. The display device of claim 1, wherein the feedback circuit is disposed between a display back plane located on an opposite side of the light-emitting circuit which is located on a front side of the display device and the light-emitting circuit.

8. The display device of claim 1, further comprising:
a reflective element configured to reflect the first light such that the first light is transferred to the light-receiving element, and
wherein the reflective element is disposed between the light-emitting element and the light-receiving element.

9. The display device of claim 8, wherein the reflective element includes at least one low refractive index layer and at least one high refractive index layer, and
wherein the reflective element totally reflects the first light to the light-receiving element.

10. The display device of claim 9, wherein the high refractive index layer is a PDL (pixel define layer), and the low refractive index layer is a black PDL.

11. A method for compensating for degradation of a display device including a light-emitting circuit, a feedback circuit, and a processor, the method comprising:
generating, by the processor, an input analog signal based on an input digital signal;
generating, by a pixel circuit of the light-emitting circuit, a first pixel signal corresponding to the input analog signal;
emitting, by a light-emitting element of the light-emitting circuit, a first light based on the first pixel signal;
generating, by a light-receiving element of the feedback circuit, a first light-receiving signal by collecting the first light;
sensing, by a feedback signal generator of the feedback circuit, the first light-receiving signal to generate a first feedback signal;
determining, by the processor, whether a first difference value between the first feedback signal and a reference input signal exceeds a threshold value; and
generating, by the processor, a first compensation signal based on determining that the first difference value exceeds the threshold value.

12. The method of claim 11, further comprising:
providing, by the processor, the first compensation signal to the pixel circuit.

13. The method of claim 12, further comprising:
generating, by the pixel circuit, a second pixel signal corresponding to the first compensation signal;
emitting, by the light-emitting element, a second light based on the second pixel signal;
generating, by the light-receiving element, a second light-receiving signal by collecting the second light;
generating, by the feedback signal generator, a second feedback signal by sensing the second light-receiving signal; and
determining, by the processor, not to generate a second compensation signal based on determining that a second difference value between the second feedback signal and the reference input signal does not exceed the threshold value.

14. The method of claim 11, wherein the display device further includes a reflective element, and
wherein the reflective element totally reflects the first light such that the first light reaches the light-receiving element.

15. The method of claim 11, wherein the feedback circuit is disposed between a display back plane located on an opposite side of the light-emitting circuit which is located on a front side of the display device and the light-emitting circuit.
